(19) United States
(12) Patent Application Publication
(10) Pub. No.: US 2008/0164606 A1
(43) Pub. Date: Jul. 10, 2008

(54) SPACERS FOR WAFER BONDING

(76) Inventors: Christoffer Graae Greisen, Valby (DK); Lior Shiv, Hilleroed (DK); Paul N. Egginton, Lyngby (DK)

Correspondence Address: FISH & RICHARDSON P.C., P.O. BOX 1022, MINNEAPOLIS, MN, 55440-1022, US

(21) Appl. No.: 11/621,045

(22) Filed: Jan. 8, 2007

(51) Int. Cl. H01L 21/46; H01L 23/32

(52) U.S. Cl. 257/726; 438/455; 438/456; 257/E21.482

(57) ABSTRACT

A deformable spacer for wafer bonding applications is disclosed. The spacer may be used to keep wafers separated until desired conditions are achieved.

### BACKGROUND

In conventional wafer bonding systems, two separate wafers typically first are stacked and aligned in an alignment apparatus and then transferred to a bonding chamber where, under desired atmospheric conditions, the wafers are bonded together. During bonding, complimentary sealing rings on the upper and lower wafers seal to form individual cavities. In order to prevent misalignment of the wafers as they are transferred from the alignment apparatus to the bonding apparatus, the wafers are clamped together in a bond tool or “jig.” The jig typically includes retractable spacers inserted between the two wafers in peripheral regions that keep the wafers apart during the atmospheric conditioning step in the bonding apparatus. The spacers are generally made from hard and high temperature materials such as stainless steel. When the intended atmospheric conditions are achieved, the retractable spacers are removed, and the wafers are brought into contact such that the sealing rings may bond.

Removal of the retractable spacers entails applying a force on the center of the wafer stack with a small wafer bow pin. The force of the wafer bow pin induces the centers of each wafer to come into contact with one another, allowing the spacers in the peripheral regions to be removed through a mechanical arrangement integrated with the bonding apparatus. However, as the spacers are removed, significant misalignment of the wafers sometimes occurs as a result of a friction force between the spacers and the wafers.

### SUMMARY

The details of one or more embodiments of the invention are set forth in the accompanying drawings and the description below. Other features and advantages of the invention will be apparent from the description and drawings, and from the claims.

### BRIEF DESCRIPTION OF THE DRAWINGS

FIG. 1 shows an example of a first and second wafer.

FIG. 2 shows an example of a jig.

FIG. 3A-3F illustrate an example process of aligning and bonding wafers.

### DETAILED DESCRIPTION

The present disclosure relates to devices and methods for wafer bonding applications.

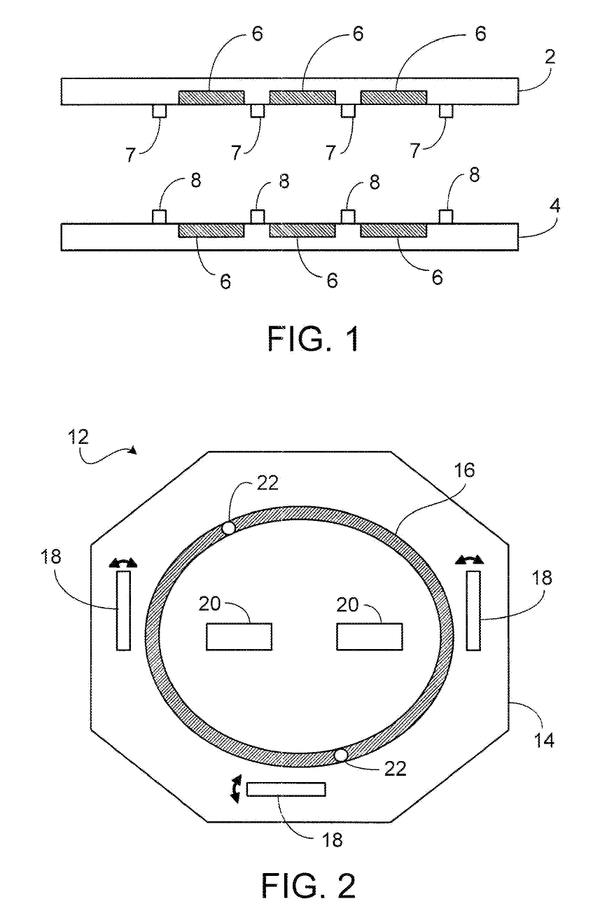

FIG. 1 shows an example of a first wafer 2 and second wafer 4 to be used in a wafer bonding process. The wafers can be formed of any material suitable for bonding applications including, for example, semiconductor, glass or plastic. Wafers 2 and 4 may incorporate devices 6 fabricated in and on their respective surfaces as a result of prior processing steps. In addition to devices, the wafers 2, 4 may include complimentary sealing rings 7 and 8. The complimentary sealing rings 7, 8 contact each other during the bonding process to form sealed cavities between the wafers. The sealing rings 7 and 8 may be formed, for example, of thin films of a gold-tin alloy having a total thickness of approximately 10 microns. When in contact, the interface of the complimentary sealing rings can, for example, undergo phase transitions to form a hermetic seal at approximately 300° C.

Before bonding, the first and second wafers are aligned and stacked in an alignment apparatus. A jig may be used in the alignment apparatus to fix wafers after they have been aligned and to transfer wafers from the alignment apparatus to a bonding chamber. An example of a jig 12 is shown in FIG. 2. The jig 12 includes a plate 14, a ring-shaped recess 16 formed in the plate, and clamps 18. The recess 16 may include one or more vacuum holes 22 for establishing a negative pressure which holds the first wafer 2 in place against the plate 14. In another implementation, an o-ring having vacuum holes may be formed on plate 14 instead of the recess 16. The plate 14 also includes holes 20 for passing light, provided by the alignment apparatus, that may be used to align the wafers optically. Such optical alignment techniques can include, for example, infrared alignment of semiconductor wafers that are transparent only to infrared light or backside alignment. The clamps 18 shown in the example jig of FIG. 2 are spring-loaded and may be rotated into position over the wafer stack once the stack is aligned. The force of the clamps 18 on the wafer stack serves to prevent misalignment of the wafers.

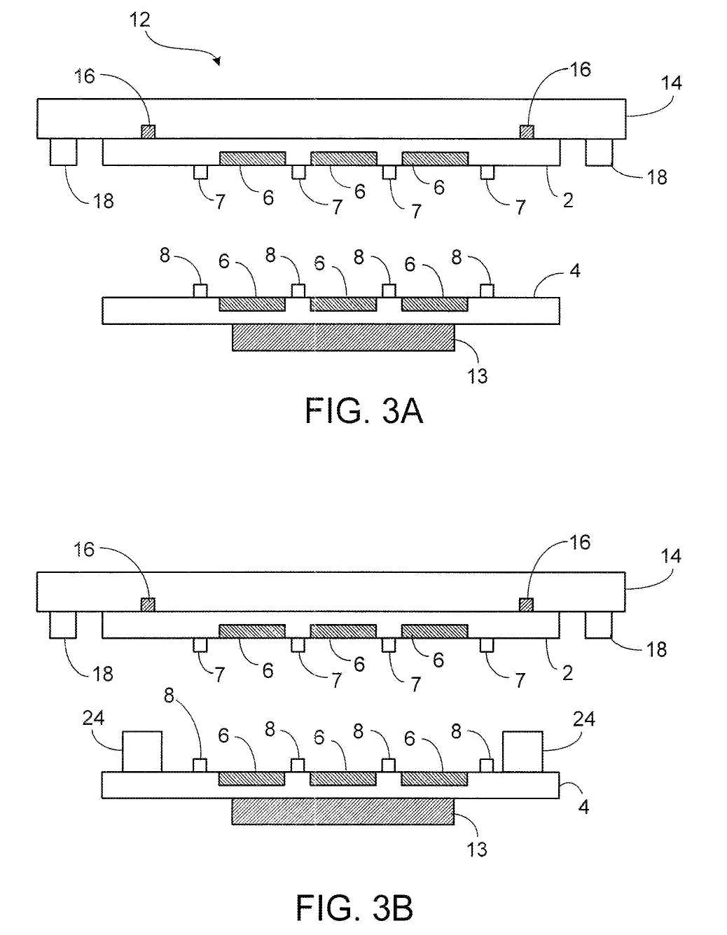

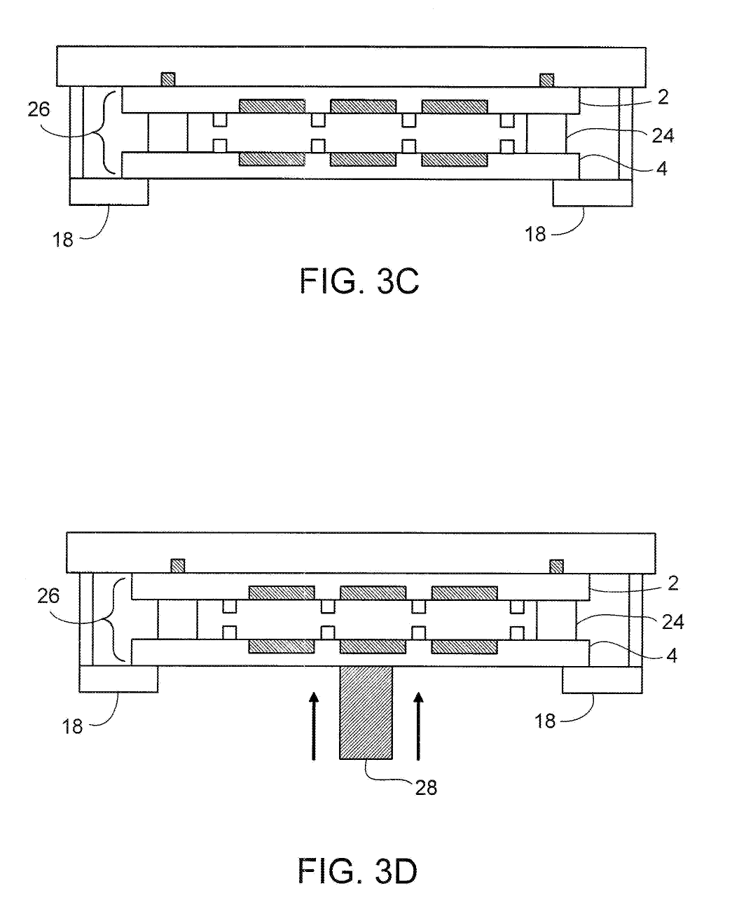

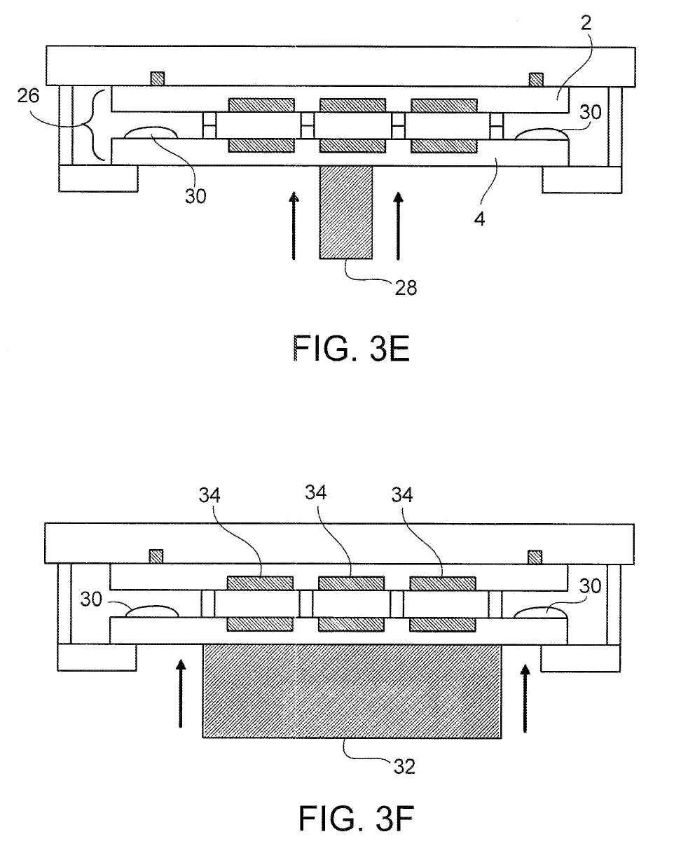

FIGS. 3A-3F illustrate an example process of aligning and bonding wafers. As shown in the example of FIG. 3A, a first wafer 2 initially is loaded onto the plate 14 of jig 12 with the individual sealing rings 7 of first wafer 2 facing away from plate 14. A negative pressure is applied through the vacuum holes 22 of the recess 16 to hold first wafer 2 in place against the plate 14. The jig 12 then is loaded wafer-side down into the alignment apparatus (not shown) and adjusted such that alignment marks on first wafer 2 are aligned with objectives in the alignment apparatus.

As shown in FIG. 3B, the second wafer 4 then is placed on a wafer translation stage or chuck 13 of the alignment apparatus located beneath the jig 12 with sealing rings 8 facing up. Deformable spacers 24 are placed on the surface of second wafer 4. The spacers 24 provide support for the first wafer 2 that is over, but initially separated from, the second wafer 4. The spacers 24 may be placed manually using tweezers or through the use of an automated tool such as, for example, a pick and place vacuum tool. In another implementation, the spacers 24 may be placed on wafer 4 using an electroplating process. The spacers 24 can be formed from a semi-hard low temperature alloy such as indium-tin (InSn) which has a melting point of approximately 125° C. Alternatively, the alloy may be silver-tin (AgSn) which has a melting point of approximately 220° C. In other implementations, the spacers 24 may be formed from a glass or polymer. In the illustrated example, the deformable spacers 24 have an area approximately equal to, for example, 1 mm by 1 mm. It is preferable that the thickness of the spacers 24 is substantially greater than the combined thickness of the sealing rings 7, 8 formed on first and second wafers 2, 4. As a result, the spacers 24 serve to prevent contact between sealing rings 7 and 8 during atmospheric conditioning in the bonding chamber. In the illustrated example, the spacers have a thickness in the range of 50 to 100 microns. After placing the spacers on the second wafer 4, the stage 13 then may be repositioned to align the second wafer 4 with the first wafer 2.

As shown in the example of FIG. 3C, clamps 18 are lifted and rotated into place underneath second wafer 4. When the clamps 18 are released, the force of the clamps fixes the position of aligned wafers 2 and 4 such that wafer stack 26 is formed. To prevent bowing of the wafers under the applied clamping force, the clamps 18 may be rotated into positions aligned with the spacer positions. Therefore, it is preferable that the spacers 24 are placed in peripheral regions of the stack 26 near the clamps 18. For example, in a 6-inch diameter wafer, six spacers may be spaced about the periphery of the wafer. The number of spacers 24 may be varied as needed. In some implementations, deformable spacers 24 having sufficient softness, e.g. a InSn alloy, may eliminate the need for clamps 18 due to a tendency of the wafers to stick or lock to the soft spacer material. In other implementations, the ambient temperature or pressure may be changed such that the hardness of spacers 24 is reduced and the wafers stick or lock to the spacer material. Using spacers instead of clamps to hold or lock the wafer stack together eliminates the clamping step and, therefore, may improve processing throughput. Furthermore, elimination of clamps may allow multiple wafers to be aligned and stacked over the initial stack 26.

After clamping the wafer stack 26, the jig 12 may be transported to a bonding chamber (not shown). Prior to bonding the wafer stack, atmospheric conditions are set in the bonding chamber. For example, the chamber may be evacuated of all gasses to create a vacuum or the chamber may be filled with a particular gas, such as SF₆ or N₂, at a specified pressure. Subsequent bonding of the wafer stack 26 retains the atmospheric conditions of the bonding chamber in the cavities created by complimentary sealing rings 7, 8.

After the desired atmospheric conditions have been met, a small wafer bow pin or mini-piston 28 may put pressure on the center of the wafer stack 26 as shown in the example of FIG. 3D. The force of the mini-piston 28 helps prevent the wafers from sliding as the spacers collapse. The temperature within the bonding chamber then is raised to a predetermined temperature, at which point the spacers can collapse by means of a phase transition from solid to liquid. For example, when using InSn alloy spacers, the temperature of the bonding chamber may be raised to 130° C. such that the InSn spacers melt. As the spacers melt, the sealing rings 7, 8 of the first wafer 2 and second wafer 4 come into contact. The liquid material of the spacers 30 may flow out of the sides of the wafer stack 26 as shown in the example of FIG. 3E. Alternatively, cavities may be formed in wafers 2 and 4 into which the liquid spacers 30 may flow.

As the wafers 2 and 4 come into contact, the temperature within the bonding chamber may continue to increase. A large piston 32 then may be applied to the wafer stack to ensure that the sealing rings are in complete contact as shown in the example of FIG. 3F. At approximately 300° C., the interface of the complimentary sealing rings can undergo phase transitions to form a hermetic seal. The chamber then is cooled such that the phase transitions are stopped. The pressure and gas composition of the cavities 34 formed by the complimentary sealing rings 7, 8 then may equal the atmospheric conditions established in a bonding chamber prior to wafer bonding.

In an alternative implementation, the deformable spacers 24 may be formed of a material that collapses, instead of melts, at a predetermined temperature. In another implementation, the deformable spacers 24 may be formed of a material that sublimates at a predetermined temperature. In yet another implementation, spacers 24 may be formed of a material that deforms under the force of pressure alone. For example, the spacers 24 may deform plastically when applying a predetermined pressure with the large piston 32. Similarly, the spacers 24 may be formed as micro-springs which compress in response to a predetermined force from the large piston.

In yet another implementation, the wafers may be separated by spacers formed of different materials that deform or change state in response to different levels of applied stimuli. For example, a first set of spacers 25 may be formed of a first material having a lower melting point than a material that forms a second set of spacers 27. As the temperature of the ambient environment reaches the melting point of the first set of spacers, the first set of spacers 25 softens such that the wafers stick or lock together. However, the second set of spacers 27, with a higher melting point, remains firm and can maintain the wafer spacing. Upon reaching the melting point of the second set of spacers, the second set of spacers 27 collapse and allow the wafers to come into contact.

Furthermore, other permanent or semi-permanent bonding techniques may be used to bond wafers together that do not require sealing rings formed of eutectic materials. Examples of other techniques includes anodic bonding, direct silicon bonding, or thermocompression bonding.

In various implementations, one or more of the following advantages may be present. Using collapsible spacers may eliminate the need for a complex mechanical setup to remove spacers prior to or during the bonding step. In addition, the use of collapsible spacers may reduce the probability of wafer misalignment that result from friction forces associated with retracting spacers. Furthermore, eliminating the spacer retraction tool may allow many bonded wafer pairs to be stacked together and bonded using the same piston.

A number of embodiments of the invention have been described. Nevertheless, it will be understood that various modifications may be made without departing from the spirit and scope of the invention. Accordingly, other implementations are within the scope of the following claims.

What is claimed is:

1. A wafer bonding process comprising:
placing a spacer between a first and second wafer to separate a first bonding surface of the first wafer from a second bonding surface of the second wafer;
aligning the first wafer above the second wafer;
transporting the wafer stack to a bonding chamber;
applying a physical stimulus to cause the spacer to change its state, thereby allowing the first bonding surface to contact the second bonding surface; and
causing the first bonding surface to bond with the second bonding surface.

2. The wafer bonding process according to claim 1 further comprising clamping the first wafer, second wafer and spacer together in a jig.

3. The wafer bonding process according to claim 1 further comprising modifying the atmospheric conditions in the bonding chamber prior to applying the physical stimulus.

4. The wafer bonding process according to claim 1 further comprising applying a force to a central portion of the first wafer or second wafer to establish a friction force between the first bonding surface and the second bonding surface.

5. The wafer bonding process according to claim 1 further comprising applying a force to the first wafer or second wafer to bond the first bonding surface to the second bonding surface.

6. The wafer bonding process according to claim 1 wherein bonding the first bonding surface to the second bonding surface comprises anodic bonding, thermocompression bonding, direct silicon bonding or eutectic bonding.

7. The wafer bonding process according to claim 1 wherein placing the spacers between the first and second wafer is automated.

8. The wafer bonding process according to claim 1 wherein placing the spacers between the first and second wafer includes an electroplating process.

9. A wafer stack comprising:
a first wafer;
a second wafer; and
a spacer adapted to separate a first bonding surface of the first wafer and a second bonding surface of a second wafer,
wherein the spacer is further adapted to change its state in response to a physical stimulus such that the first bonding surface contacts the second bonding surface.

10. The wafer stack of claim 9 wherein the physical stimulus is a change in ambient temperature.

11. The wafer stack of claim 9 wherein the physical stimulus is a change in pressure on the spacer.

12. The wafer stack of claim 9 wherein the spacer comprises an alloy.

13. The wafer stack of claim 12 wherein the alloy is InSn.

14. The wafer stack of claim 12 wherein the alloy is AgSn.

15. The wafer stack of claim 9 wherein the spacer comprises a polymer.

16. The wafer stack of claim 9 wherein the spacer comprises a glass.

17. The wafer stack of claim 9 wherein the spacer comprises a spring.

18. The wafer stack of claim 9 wherein the spacer comprises a material that sublimates.

19. The wafer stack of claim 9 wherein the first and second bonding surfaces are sealing rings.

20. The wafer stack of claim 19 wherein the sealing rings comprise a eutectic alloy.

21. The wafer stack of claim 19 wherein a first sealing ring is Au and a second sealing ring is Sn.

22. The wafer stack of claim 9 wherein at least one of the first or second wafers comprises a semiconductor.

23. A method of bonding wafers comprising:
placing a spacer between a first wafer and a second wafer, wherein the spacer separates a first bonding surface of the first wafer from a second bonding surface of the second wafer;
applying a first physical stimulus to cause the spacer to change its state, allowing the first bonding surface to contact the second bonding surface; and
bonding the first bonding surface to the second bonding surface.

24. A method of bonding wafers according to claim 23 wherein a cavity is created between the first and second wafers when the first bonding surface contacts the second bonding surface.

25. A method of bonding wafers according to claim 24 wherein the atmosphere inside of the cavity comprises a vacuum.

26. A method of bonding wafers according to claim 24 wherein the atmosphere inside of the cavity comprises a gas.

27. A method of bonding wafers according to claim 23 wherein the bonding is performed in a vacuum.

28. A method of bonding wafers according to claim 23 wherein the first physical stimulus comprises an increase in temperature.

29. A method of bonding wafers according to claim 28 wherein the change in state of the spacer comprises melting of the spacer.

30. A method of bonding wafers according to claim 28 wherein the change in state of the spacer comprises sublimation of the spacer.

31. A method of bonding wafers according to claim 23 wherein the first physical stimulus comprises an increase in pressure.

32. A method of bonding wafers according to claim 31 wherein the change in state of the spacer comprises plastic deformation of the spacer.

33. A method of bonding wafers according to claim 31 wherein the change in state of the spacer comprises compression of the spacer.

34. A method of bonding wafers according to claim 23 further comprising clamping the first and second wafer.

35. A method of bonding wafers according to claim 23 further comprising applying a second physical stimulus prior to applying the first physical stimulus, wherein the second physical stimulus causes the spacer to change its state, allowing the wafers to remain fixed in place.

36. A method of bonding wafers according to claim 23 further comprising:
placing a second spacer between a first wafer and a second wafer; and
applying a second physical stimulus to cause the second spacer to change its state, allowing the wafers to remain fixed in place.

37. A method of bonding wafers comprising:
placing a plurality of wafers in a stack;
placing spacers between each pair of wafers in the stack, wherein each spacer separates a first bonding surface of a first wafer in each pair of wafers from a second bonding surface of an adjacent wafer in the pair;
placing the wafer stack in a bonding chamber;
applying a physical stimulus to cause the spacers to change their state, allowing the first bonding surface of the first wafer in each pair to contact the second bonding surface of the adjacent wafer in each pair; and
bonding the first bonding surface of the first wafer in each pair to the second bonding surface of the adjacent wafer in each pair.
